(19) United States
(12) Patent Application Publication
(10) Pub. No.: US 2015/0155849 A1
(43) Pub. Date: Jun. 4, 2015

(54) SURFACE MOUNTING QUARTZ CRYSTAL UNIT AND METHOD OF FABRICATING THE SAME

(71) Applicant: NIHON DEMPA KOGYO CO., LTD., TOKYO (JP)

(72) Inventor: KENICHI KIKUCHI, SAITAMA (JP)

(21) Appl. No.: 14/513,221

(22) Filed: Oct. 14, 2014

(30) Foreign Application Priority Data
Nov. 29, 2013 (JP) 2013-247004
Mar. 11, 2014 (JP) 2014-047445

(51) Int. Cl. H03H 9/17; B23K 1/00; H03H 9/215

(52) U.S. Cl. CPC H03H 9/172; H03H 9/215; B23K 1/0016; B23K 2001/12

(57) ABSTRACT

A surface mounting quartz crystal unit includes a ceramic substrate, a holding terminal, a metal cover, a signal line terminal and a ground terminal, and a metal layer. The holding terminal holds a crystal resonator on the substrate. The metal cover is arranged to cover the crystal resonator. The signal line terminal and a ground terminal are formed on a rear surface of the substrate. The metal layer bonds the substrate to the metal cover at a part on a front surface of the substrate. The part is in contact with the metal cover. The substrate has a first through via inside the substrate. The first through via connects the holding terminal to the signal line terminal. The substrate has a through conductor at the substrate. The through conductor connects the metal layer to the ground terminal.

### CROSS-REFERENCE TO RELATED APPLICATIONS

This application claims the priority benefit of Japan patent application serial no. 2013-247004, filed on Nov. 29, 2013 and Japan patent application serial no. 2014-047445, filed on Mar. 11, 2014. The entirety of each of the above-mentioned patent applications is hereby incorporated by reference herein and made a part of the specification.

### TECHNICAL FIELD

This disclosure relates to a surface mounting quartz crystal unit, and in particular to a surface mounting quartz crystal unit that can block noises from outside a metal cover to a quartz crystal unit inside the metal cover and a method of fabricating the same.

### DESCRIPTION OF THE RELATED ART

Since conventional quartz crystal units have seen a large decrease in selling price, a quartz crystal unit that uses a single layer ceramic sheet and the like are mass-produced to reduce manufacturing costs. However, since resin is used for sealing a metal cover (lid) and a ceramic substrate (base), deterioration in electrical characteristics due to aging is seen.

Glass or metal is used for sealing with high airtightness, but it is not proper to use glass for sealing ceramic sheets when the positioning of the lid and breaking stress are taken into consideration. Accordingly, it is considered that a configuration that seals the ceramic sheet and the metal lid with a metal material is properly adopted.

As the relevant prior art, Japanese Patent Publication No. 2011-155172 “ELECTRONIC APPARATUS, AND METHOD OF MANUFACTURING THE SAME” (Seiko Epson Corporation) [Patent Literature 1], Japanese Patent Publication No. 2013-140876 “MANUFACTURING METHOD OF ELECTRONIC DEVICE, ELECTRONIC DEVICE, PIEZOELECTRIC OSCILLATOR, AND ELECTRONIC APPARATUS” (Seiko Epson Corporation) [Patent Literature 2], and Japanese Patent No. 3541682 “PIEZOELECTRIC VIBRATOR” (Seiko Epson Corporation) [Patent Literature 3] are disclosed.

Patent Literature 1 discloses that an electronic apparatus is brazed with the use of metal when the ceramic base and the metal lid are bonded. Patent Literature 2 discloses that an electronic device is laser-welded with the use of metal when the ceramic base and the metal lid are bonded. Patent Literature 3 discloses that a sealing material for a piezoelectric vibrator, made of a metal of gold or silver, is dissolved by irradiating a laser beam or an electron beam when the ceramic base and the metal lid are bonded.

However, the conventional quartz crystal unit described above has a problem that sufficient consideration is not given to noises from outside the metal lid affecting the crystal resonator inside the metal lid when the ceramic sheet and the metal lid are sealed with a metal material.

In addition, Patent Literatures 1 to 3 do not disclose considerations for noises outside the metal cover affecting the crystal resonator inside the metal cover.

A need thus exists for a surface mounting quartz crystal unit and a method of fabricating the surface mounting quartz crystal unit which are not susceptible to the drawback mentioned above.

### SUMMARY

A surface mounting quartz crystal unit according to the disclosure includes a ceramic substrate, a holding terminal, a metal cover, a signal line terminal, a ground terminal, and a metal layer. The holding terminal holds a crystal resonator on the substrate. The metal cover is arranged to cover the crystal resonator. The signal line terminal and the ground terminal are formed on a rear surface of the substrate. The metal layer bonds the substrate to the metal cover at a part on the front surface of the substrate that is in contact with the metal cover. The substrate has a first through via inside the substrate. The first through via connects the holding terminal to the signal line terminal. The substrate has a through conductor (second through via) at the substrate. The through conductor connects the metal layer to the ground terminal.

### BRIEF DESCRIPTION OF THE DRAWINGS

The foregoing and additional features and characteristics of this disclosure will become more apparent from the following detailed description considered with reference to the accompanying drawings.

FIG. 1 is a perspective view illustrating a crystal unit with an open metal cover according to an embodiment of this disclosure.

FIG. 2 is an explanatory cross-sectional view illustrating the crystal unit.

FIGS. 3A and 3B are explanatory plan views illustrating the crystal unit.

FIG. 4 is an explanatory cross-sectional view taken along the line IV-IV of FIG. 3A.

FIG. 5 is an explanatory cross-sectional view taken along the line V-V of FIG. 3A.

FIG. 6 is an explanatory cross-sectional view taken along the line VI-VI of FIG. 3A.

FIGS. 7A to 7C are explanatory cross-sectional views illustrating a method of fabricating the crystal unit.

FIGS. 8A and 8B are explanatory plan views illustrating a double-sided unit.

FIGS. 9A and 9B are explanatory plan views illustrating another double-sided unit.

FIG. 10 is an explanatory cross-sectional view illustrating the crystal unit when a U-shaped metal lid is used.

FIG. 11 is a perspective view illustrating a tuning-fork quartz crystal unit with an open metal cover.

FIG. 12 is an explanatory cross-sectional view illustrating a crystal unit according to a second application before a temporary attaching process.

FIG. 13 is an explanatory cross-sectional view illustrating the crystal unit according to the second application after the temporary attaching process.

FIG. 14 is an explanatory cross-sectional view illustrating the crystal unit according to the second application after the sealing process.

FIGS. 15A and 15B are explanatory plan views illustrating a metal cover according to the second application.

FIG. 16 is an explanatory cross-sectional view illustrating a crystal unit according to a third application.

FIG. 17 is an explanatory schematic cross-sectional view illustrating a crystal unit according to a fourth application.

### DETAILED DESCRIPTION

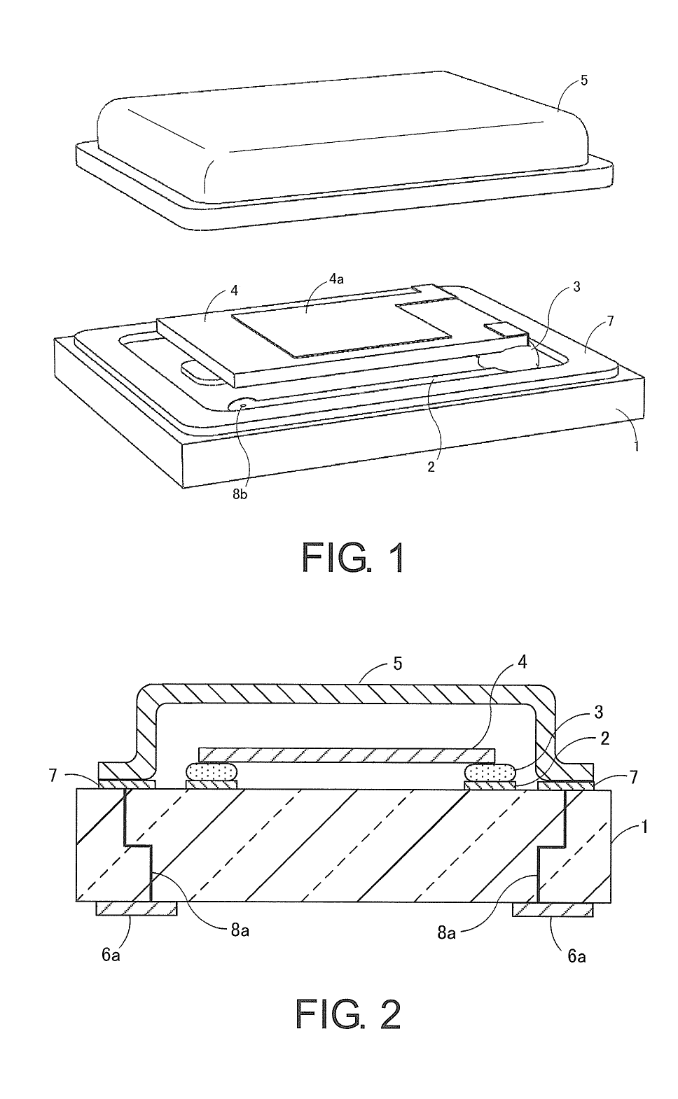

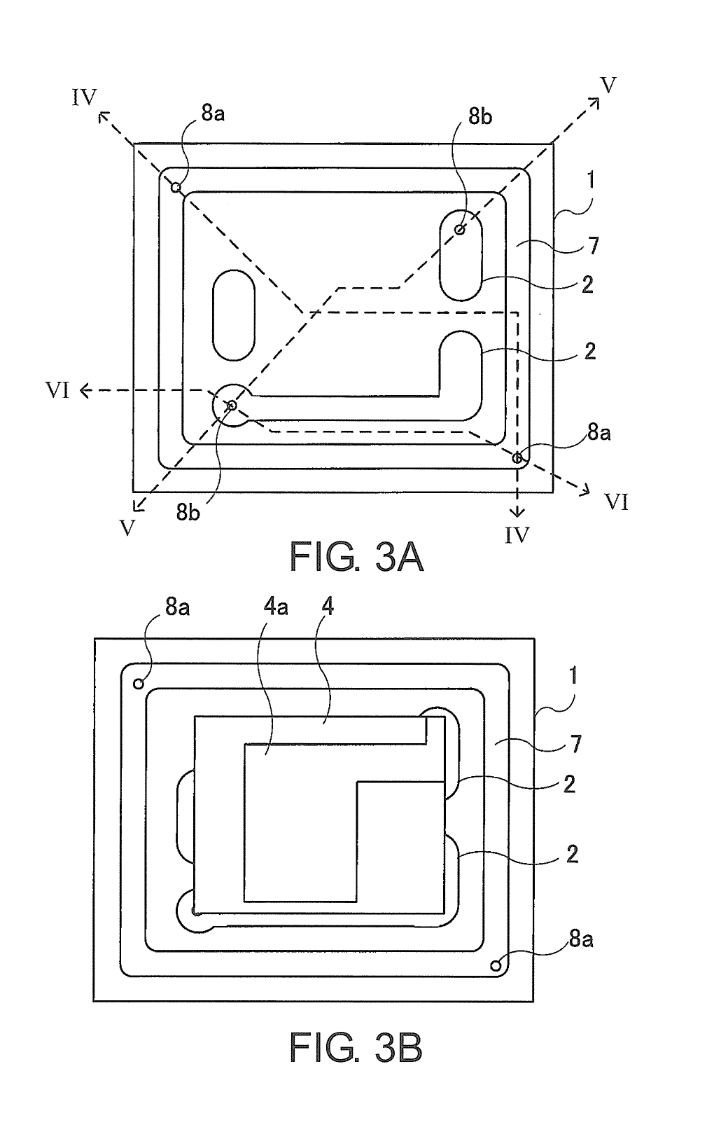

A description will be given of an embodiment according to this disclosure with reference to the drawings. A surface mounting quartz crystal unit according to the embodiment of this disclosure is arranged to connect the holding terminal that holds a crystal element on the front surface of the ceramic substrate with the signal line terminal that is formed on the rear surface of the substrate through the first through via that is formed in the substrate, and to connect the metal layer that is formed at the part that is in contact with the metal cover with the ground terminal that is formed on the rear surface of the substrate through the through conductor (second through via) that is formed in the substrate. Because the metal cover is connected with the ground terminal, therefore noises from outside the metal cover can be prevented from penetrating inside the metal cover, and the airtightness can be improved because the metal cover and the ceramic substrate are sealed with the metal layer.

[The Crystal Unit: FIG. 1, FIG. 2, FIGS. 3A and 3B]

A description will be given of the surface mounting quartz crystal unit (the crystal unit) according to the embodiment of this disclosure with reference to FIG. 1, FIG. 2, and FIGS. 3A and 3B. FIG. 1 is a perspective view with a metal cover of the crystal unit in opened state. FIG. 2 is an explanatory cross-sectional view of the crystal unit, and FIGS. 3A and 3B are schematic plan views of the crystal unit. Here, in order to make it easy to understand the characteristic parts, the drawing that excludes the metal cover, the crystal element, and the like is illustrated in FIG. 3A, and the drawing with the crystal element mounted is illustrated in FIG. 3B. In addition, an embodiment that includes the ceramic sheet with two layers is given in FIG. 2. As illustrated in FIG. 1, FIG. 2, and FIGS. 3A and 3B, the crystal unit includes a ceramic substrate 1, holding terminals 2, conductive adhesives 3, a crystal element 4, a metal cover (metal lid) 5, ground terminals 6a, signal line terminals 6b (illustrated in FIG. 5), metal layer 7, through via for ground 8a and through via for signal line 8b. Here, the through via for ground 8a and the through via for signal line 8b correspond to the second through via in the claims and the first through via in the claims, respectively.

[Each Part of the Crystal Unit]

The ceramic substrate 1 mounts the crystal element 4 on the front surface thereof through the holding terminals 2 and the conductive adhesives 3, and further includes the metal cover 5, the ground terminals 6a and the signal line terminals 6b are formed on the rear surface thereof, and the through via for ground 8a and the through via for signal line 8b are formed inside thereof. The ceramic sheet is divided into plural parts to form the ceramic substrate 1 and has any of one layer, two layers or three layers.

Each holding terminal 2 that is formed on the substrate 1 is formed of metal film and is connected to the through via for signal line 8b. FIG. 3B illustrates a cantilevered unit where the crystal element 4 is held at one short side, one holding terminal 2 is connected to the through via for signal line 8b at the short side of the substrate 1, and another holding terminal 2 is drawn out to the opposite short side along the long side of the substrate 1, and is connected to the through via for signal line 8b. In addition, excitation electrodes 4a are formed on the front and the rear surfaces of the crystal element 4. As described later, this disclosure is not limited to a cantilevered unit, and may be applied to a double-sided quartz crystal unit.

The conductive adhesive 3 is an adhesive that has conductivity used to bond the crystal element 4 to the holding terminal 2. The crystal element 4 is a quartz crystal unit, with electrodes formed on the front surface and the rear surface, and each electrode is bonded to a different holding terminal 2 by the conductive adhesive 3.

The metal cover (metal lid) 5 is formed so as to cover the mounted crystal element 4. Here, the metal lid has a cavity (a space that houses the crystal element 4) that is produced by drawing. In the crystal unit, the metal lid 5 has a structure with an L-shaped flange with respect to the ceramic substrate 1. Kovar, nickel silver, 42 alloy, SUS (Special Use Stainless steel), and the like are used as the material of the lid. Two ground terminals 6a are formed on the rear surface of the substrate 1. The two ground terminals 6a are connected to the through via for ground 8a. Two signal line terminals 6b are formed on the rear surface of the substrate 1. The two signal line terminals 6b are connected to the through via for signal line 8b.

As for the metal layer 7, an alloy such as gold-tin (Au—Sn), gold-germanium (Au—Ge), silver solder, and silver-tin (Ag—Sn) are used as a sealing material. Each of the sealing materials are used as a type of adhesive after dissolving an alloy (a brazing alloy) that has a lower melting point than the member to be bonded. The sealing material is formed by preform, plating, clad material and paste. In addition to laser and electron beam, collective heat processing, vacuum reflow processing, and the like are used as sealing methods. Also, the metal layer 7 may be formed by metallization. Metallization is to form a metal layer on the front surface of the ceramic substrate 1, then braze metal to form a metal film on the front surface of the non-metal.

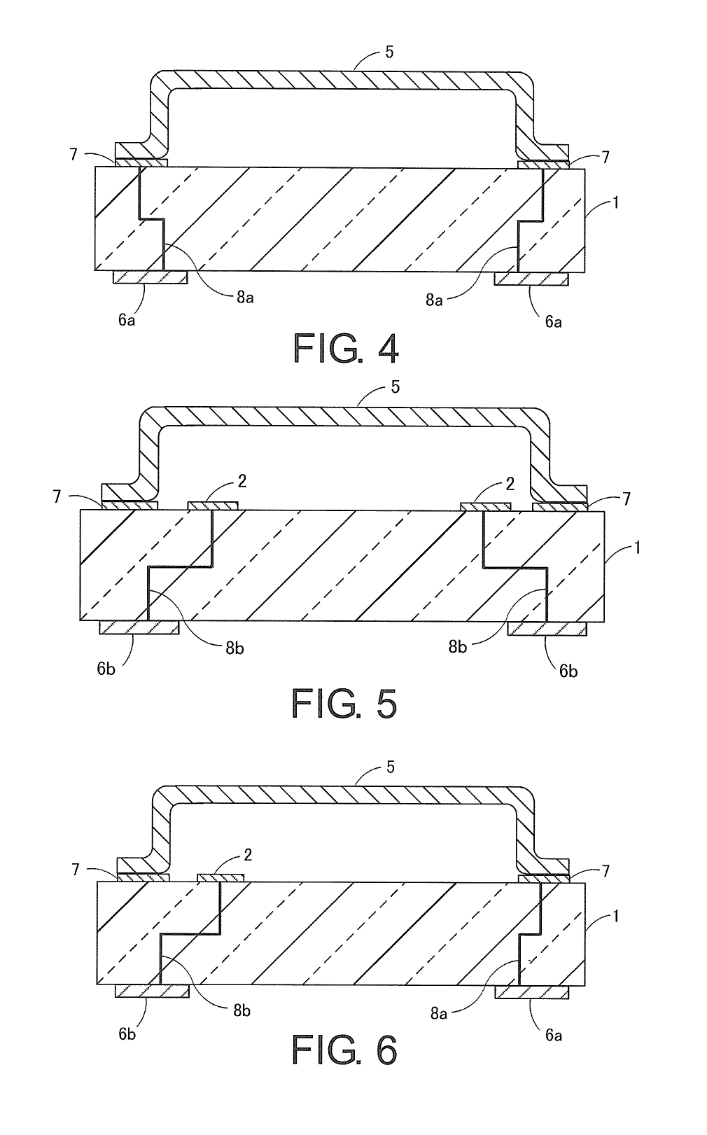

Each of the through via for ground 8a forms a via hole in the substrate 1, then forms a conductor on the inside thereof by plating, connecting the metal layers 7 and ground terminals 6a with a conductive material. Therefore, since the ground terminals 6a are connected to ground level, all of the ground terminals 6a, the through via for ground 8a, the metal layer 7 and the metal lid 5 become ground level. Each of the through via for signal line 8b forms a via hole in the substrate 1, then forms a conductor on the inside thereof by plating, connecting the holding terminals 2 and the signal line terminals 6b with a conductive material.

[Various Cross-Sectional Surfaces: FIGS. 4 to 6]

Next, a description will be given of various cross-sectional surfaces according to the crystal unit with reference to FIGS. 4 to 6. FIG. 4 is an explanatory cross-sectional view taken along the line IV-IV of FIG. 3A, FIG. 5 is a schematic cross-sectional view taken along the line V-V of FIG. 3A, and FIG. 6 is a schematic cross-sectional view taken along the line VI-VI of FIG. 3A. In particular, an embodiment that includes the ceramic sheet with two layers is given in FIGS. 4 to 6.

[Explanatory Cross-Sectional View Taken Along the Line IV-IV: FIG. 4]

FIG. 4 illustrates a state where the metal layer 7 contacts the metal lid 5 and is connected to the through via for ground 8a that is formed on the substrate 1, and where the through via for ground 8a is connected to the ground terminals 6a.

[Explanatory Cross-Sectional View Taken Along the Line V-V: FIG. 5]

FIG. 5 illustrates a state where the holding terminals 2 are connected to the through via for signal lines 8b that is formed on the substrate 1, and where the through via for signal lines 8b are connected to the signal line terminals 6b.

[Explanatory Cross-Sectional View Taken Along the Line VI-VI: FIG. 6]

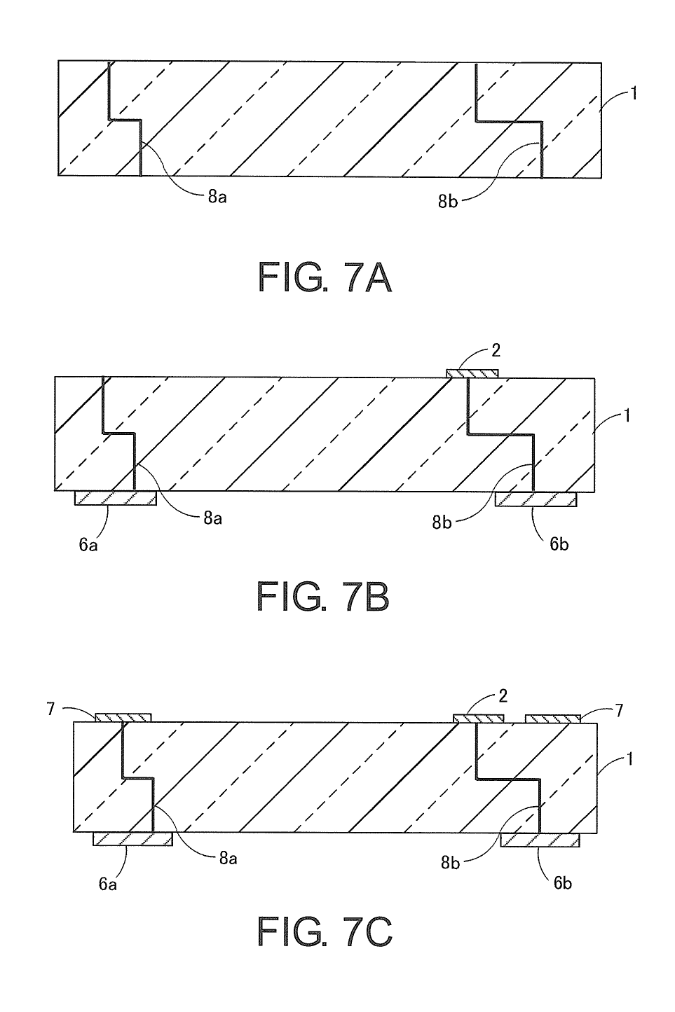

The right side of FIG. 6 illustrates a state where the metal layer 7 that contacts the metal lid 5 is connected to the through via for ground 8a that is formed on the substrate 1, and where the through via for ground 8a is connected to the ground terminal 6a. In addition, the left side of FIG. 6 illustrates a state where the holding terminal 2 is connected to the through via for signal line 8b that is formed on the substrate 1, and where the through via for signal line 8b is connected to the signal line terminal 6b.

[Method of Fabricating the Crystal Unit: FIGS. 7A to 7C]

Next, a description will be given of a method of fabricating the crystal unit with reference to FIGS. 7A to 7C. FIGS. 7A to 7C are explanatory cross-sectional views illustrating a method of fabricating the crystal unit. Here, a description will be given of the method of fabricating the crystal unit in FIGS. 7A to 7C with reference to the schematic cross-sectional view in FIG. 6. As illustrated in FIG. 7A, the through via for ground 8a and the through via for signal line 8b are formed in the substrate 1. When the crystal unit is arranged to include four terminals on the rear surface of the substrate 1, two through via for ground 8a and two through via for signal line 8b are formed.

As illustrated in FIG. 7B, the ground terminal 6a and the signal line terminal 6b are formed on the rear surface of the substrate 1, and the holding terminal 2 is formed on the front surface of the substrate 1. As illustrated in FIG. 7C, metal layer 7 is formed at the part that is in contact with the metal lid 5 on the front surface of the substrate 1. The metal layer 7 is formed in a belt shape at the inner circumference of the substrate 1. When the metal layer 7 is used as the sealing material, the metal layer 7 is formed of a preform, plating, a clad material and a paste. Also, the metal layer 7 may be formed by metallization.

Then, the crystal element 4 that is bonded with the conductive adhesive 3 is mounted on the holding terminal 2, a contact surface of the metal lid 5 is arranged on the metal layer 7 by positioning, and in addition to laser and electron beam, the metal lid 5 can be sealed on the substrate 1 by collective heat processing, vacuum reflow processing, and the like. After the sealing process, division processing such as blade dicing, laser dicing or breaking along a scribe line (break line), which is formed on the ceramic sheet, is performed, the individual surface mounting quartz crystal units are obtained accordingly.

[Sealing Method]

As a sealing method, a plurality of crystal element 4 are arranged so as to direct downward, mounted on the ceramic sheet, and a plurality of metal lids 5 are aligned in an alignment pallet, then the pallet and the ceramic sheet are positioned and collectively sealed by applying heat and pressure. In this case, if a clearance is formed between the ceramic sheet and the metal lid 5, outgas generated by the sealing process can be released to the outside.

[Another Sealing Method]

In addition, as another sealing method, the metal lid 5 is temporarily attached to the ceramic sheet that is provided with the crystal element 4 one by one. An ultrasonic wave, heating device, laser, and the like are used for temporary attaching. However, if it is completely airtight during temporary attachment, internal gas cannot be released. Therefore, some gap needs to be formed between the metal lid 5 and the metal layer 7. As a method of forming the gap, the thickness of the metal layer 7 can intentionally be made non-uniform and partially changed to form a gap intentionally. When laser is used for temporary attachment, local heating is performed by laser to fix temporarily.

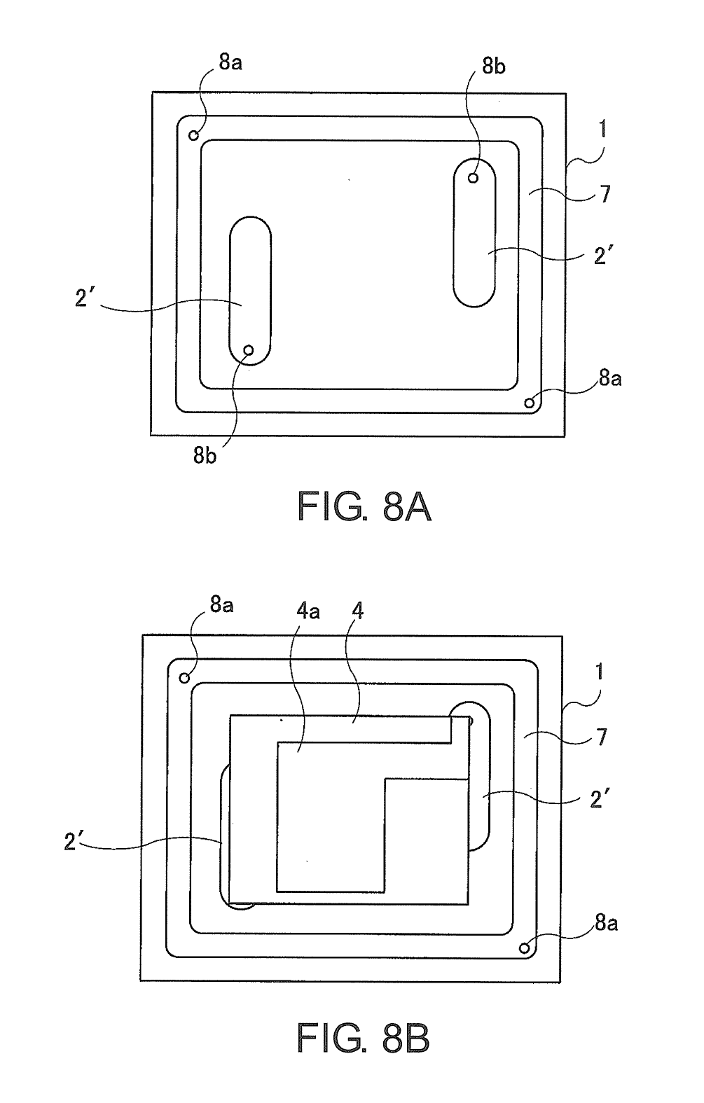

After temporary attachment, the ceramic sheet is heated by vacuum reflow processing and the metal layer 7 of the sealing material is melted to perform the sealing. Before the vacuum reflow processing, if formic acid reflow processing is performed, the leakage (airtightness) can be improved and the self-alignment property can be increased. Since the formic acid reflow processing can be reduced at about 150° C. to 200° C. (reduction), the formic acid can be reduced before the softening of the sealing material.

[Double-Sided Unit: FIGS. 8A and 8B]

Next, a description will be given of an example of a double-sided unit in the surface mounting quartz crystal unit according to the embodiment of this disclosure. FIGS. 8A and 8B are explanatory plan views of a double-sided unit. The drawing that excludes the metal cover and the crystal element is illustrated in FIG. 8A, and the drawing with the crystal element mounted is illustrated in FIG. 8B. As for the double-sided unit, as illustrated in FIGS. 8A and 8B, the through via for ground 8a and the through via for signal line 8b are formed in the ceramic substrate 1, and a holding terminal 2′ that holds one short side of the crystal element 4 and the holding terminal 2′ that holds the other short side of the crystal element 4 are formed on each of the through via for signal line 8b. Then, excitation electrodes 4a are formed on the front and the rear surfaces of the crystal element 4. In addition, the metal layer 7 is formed on the through via for ground 8a.

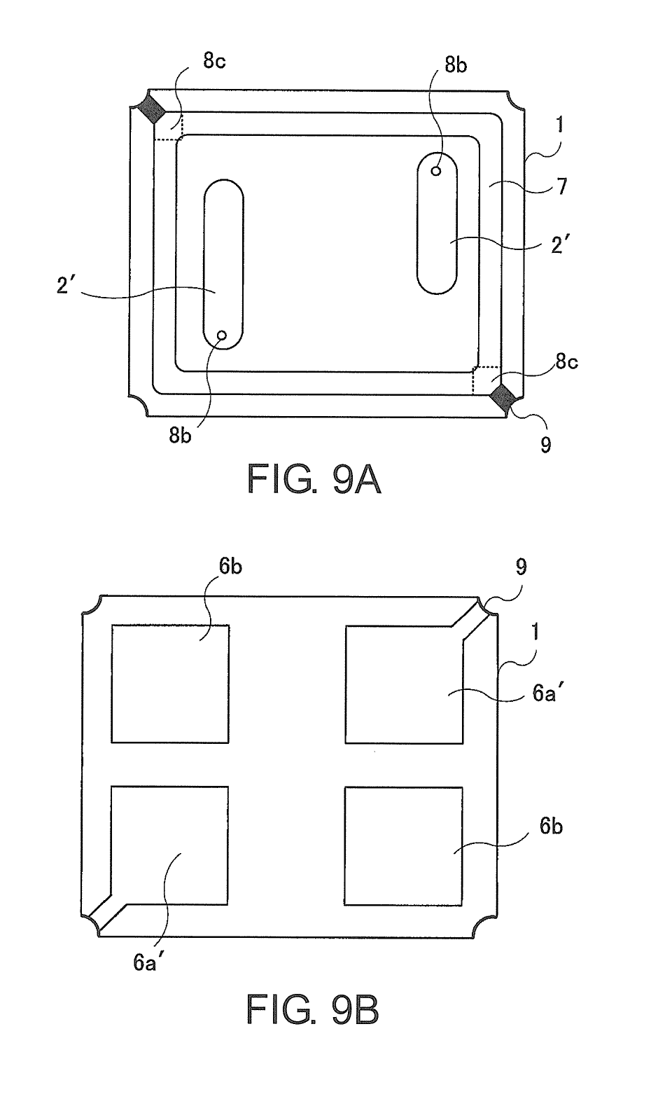

The metal layer 7 is formed in a belt shape at the inner circumference of the substrate 1, similar to FIGS. 3A and 3B. In addition, each of the holding terminals 2′ is formed such that the end portion on the side opposite to the side that is connected to the through via for signal line 8b is shortened in the sort side direction. This is useful for preventing the metal lid 5 from contacting the holding terminal 2′ even if the mounting position of the metal lid 5 is deviated.

[Schematic Plan View of Another Double-Sided Unit: FIGS. 9A and 9B]

Next, a description will be given of another double-sided surface mounting quartz crystal unit with reference to FIGS. 9A and 9B. FIGS. 9A and 9B are explanatory plan views of another double-sided unit. In particular, the front surface of another double-sided unit and the rear surface of another double-sided unit are illustrated in FIG. 9A and FIG. 9B, respectively. As illustrated in FIG. 9A, as for another double-sided unit, through-holes are formed at four corners of the substrate 1, and through terminals 9 are formed on the side surface (side wall) of the through-holes.

In particular, two corners of the four corners of the substrate 1 are connected to connection terminals for ground 8c, and are connected to ground terminals 6a′ in FIG. 9B through the through terminals 9. However, the holding terminals 2′ are connected to the signal line terminals 6b of the rear surface through the through via for signal line 8b. In the example of FIGS. 9A and 9B, the ground connection is performed not by a via of substrate 1 but by the through terminals 9 at the corner of the substrate 1. This configuration can be applied to the cantilever type surface mounting quartz crystal unit.

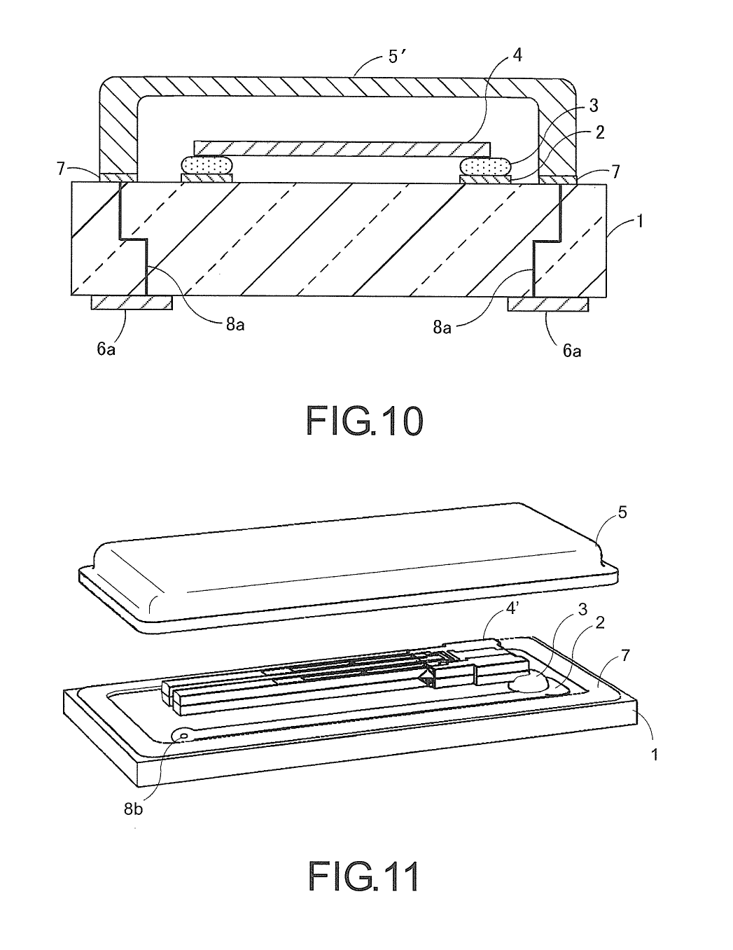

First Application: FIG. 10

Next, this can also be applied to a U-shaped metal lid. FIG. 10 is an explanatory cross-sectional view of the crystal unit when a U-shaped metal lid is used. In FIG. 10, a U-shaped metal lid 5′ that has no flange is used. As a result, this can provide a larger internal space than that of the structure of metal lid 5 which has an opening face of the flange illustrated in FIG. 1 and FIG. 2. Therefore, as a result of further miniaturization of the surface mounting quartz crystal unit is possible. Here, in order to widen the contact surface of the metal lid 5′ to the metal layer 7, the side walls in the vertical direction are formed to be thicker than the top plate part in the horizontal direction.

[Tuning-Fork Quartz Crystal Unit: FIG. 11]

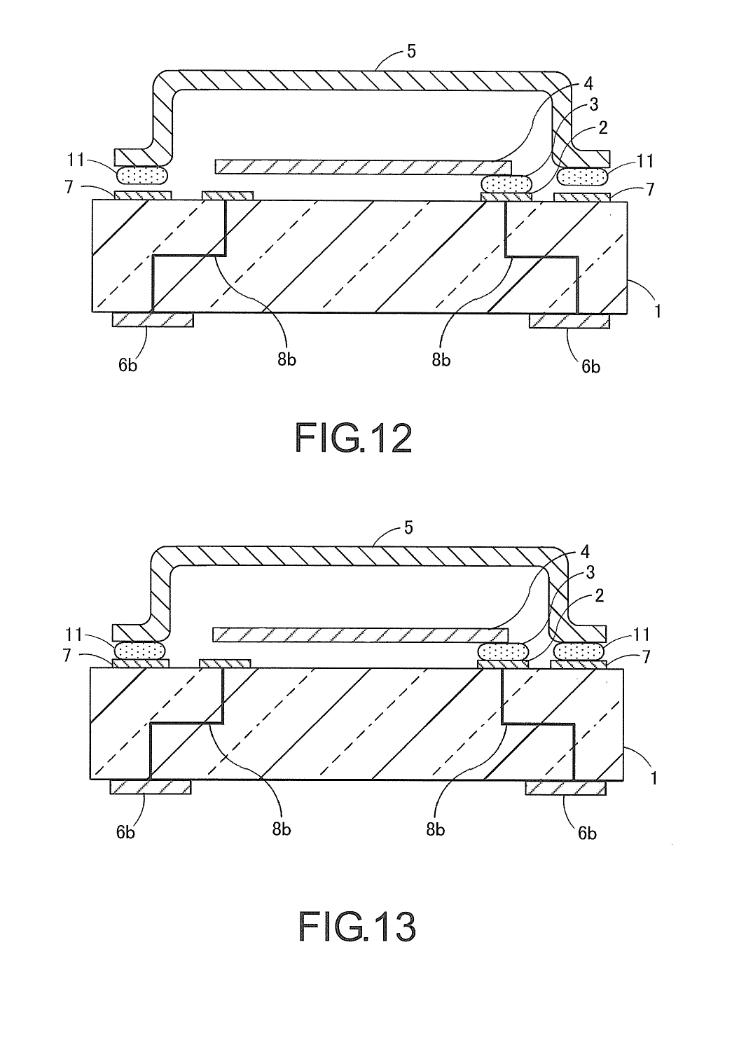

Surface mounting quartz crystal units were described in detail above; however, it may be applied to a tuning-fork quartz crystal unit as illustrated in FIG. 11. FIG. 11 is a perspective view with the metal cover of a tuning-fork quartz crystal unit in an opened state. As illustrated in FIG. 11, the tuning-fork quartz crystal unit includes the metal layer 7 and the holding terminal 2 that are formed on the ceramic substrate 1, and a tuning-fork crystal element (crystal resonator) 4′ mounted on the holding terminal 2 through the conductive adhesive 3. Here, the holding terminal 2 is drawn out along a long side of the ceramic substrate 1, and connected to the through via for signal line 8b at the end portion, and is connected to the signal line terminal that is formed on the rear surface of the ceramic substrate 1.

[Second Application (Flux Layer): FIGS. 12 To 15B]

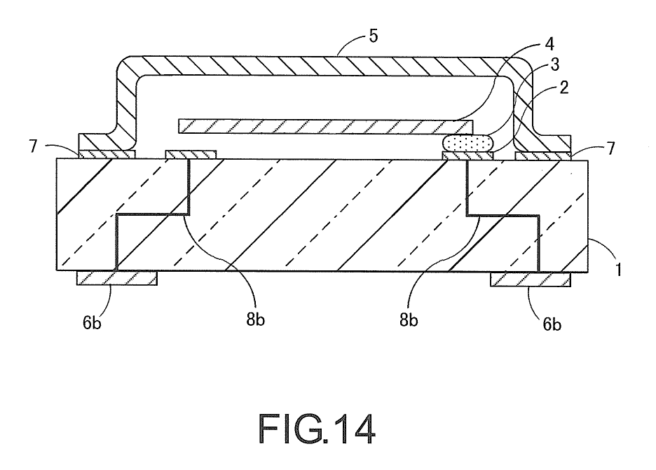

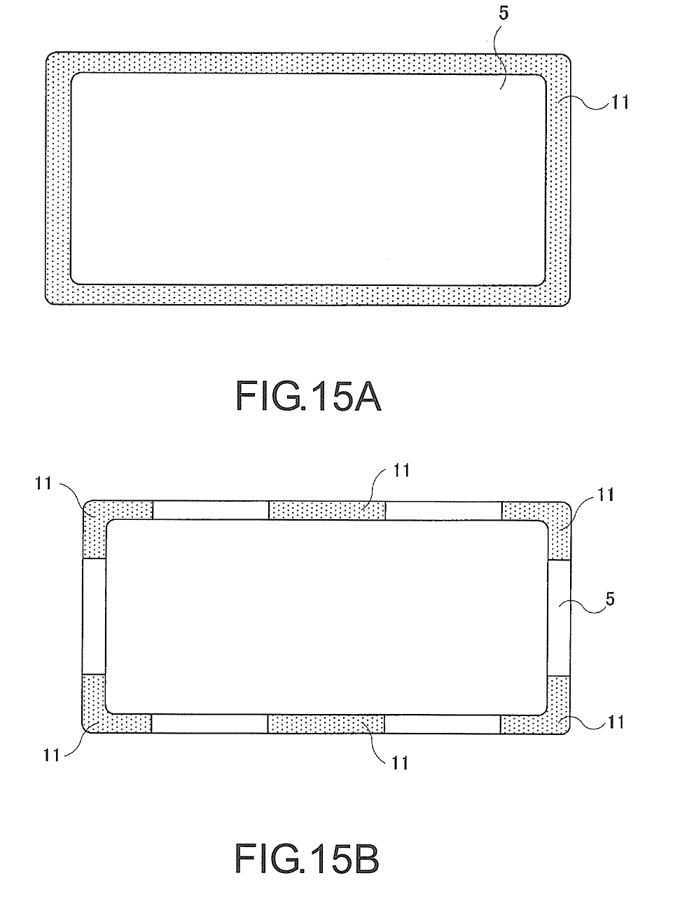

Next, a description will be given of the surface mounting quartz crystal unit of a second application according to the embodiment of this disclosure with reference to FIGS. 12 to 15B. FIG. 12 is an explanatory cross-sectional view of a unit of a second application before the temporary attaching process, FIG. 13 is a schematic cross-sectional view of the crystal unit of the second application after the temporary attaching process, FIG. 14 is a schematic cross-sectional view of the crystal unit of the second application after the sealing process, and FIGS. 15A and 15B are a schematic plan view of the metal cover of the second application. A configuration in the crystal unit of the second application, as illustrated in FIGS. 12 to 15B, is basically similar to that of the previous crystal units. However, the crystal unit of the second application is different from the previous crystal units in that a flux layer 11 is formed on the contact surfaces between the metal cover (metal lid) 5 and the metal layer 7.

A description will be given of the flux layer 11 in the crystal unit of the second application. Since the other configurations in the crystal unit of the second application is similar to that of the previous crystal unit, a description thereof will not be given. An organic flux with high viscosity is used for the flux layer 11 and is applied to the contact surface between the metal lid 5 and the metal layer 7.

Here, as illustrated in FIG. 15A, the flux layer 11 may be formed on the entire contact surface between the metal lid 5 and the metal layer 7. Alternatively, as illustrated in FIG. 15B, the flux layers 11 may be partly formed on the contact surface between the metal lid 5 and the metal layer 7.

In the crystal unit of the second application, as illustrated in FIG. 12, when the metal lid 5 with the flux layer 11 applied to the contact surface is mounted on the metal layer 7, as illustrated in FIG. 13, the flux layer 11 is temporarily attached to the metal layer 7, so the metal lid 5 is temporarily fixed to the metal layer 7. In the crystal unit of the second application, as illustrated in FIG. 14, the flux layer 11 is vaporized by a sealing process such as vacuum reflow processing, to seal the metal lid 5 in close contact with the metal layer 7.

In the crystal unit of the second application, even though the metal lid 5 is mounted on the metal layer 7, the metal lid 5 is not bonded to the metal layer 7. Therefore, the outgas generated during the sealing process can be released to the outside of the metal lid 5. Here, although the flux layer 11 is vaporized by the sealing process, some residue is left.

[Effect of Crystal Unit According to Second Application]

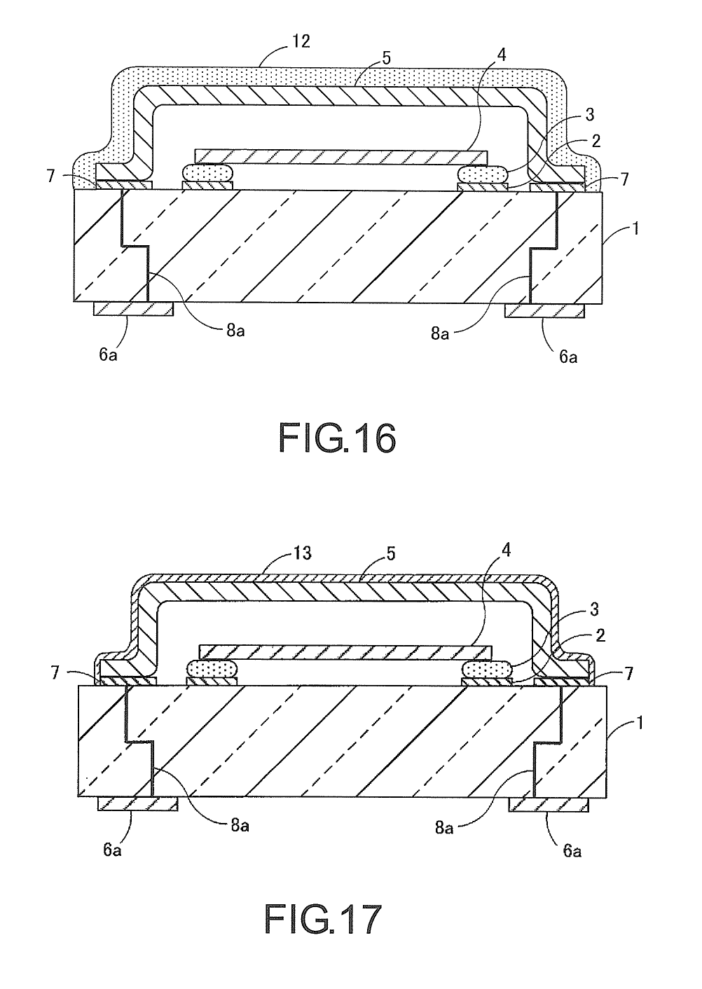

According to the crystal unit of the second application, on the front surface of the ceramic substrate 1, the metal layer 7 to bond the ceramic substrate 1 and the metal lid 5 is formed at the part where the metal lid 5 comes in contact with the front surface of the ceramic substrate 1, and a flux layer 11 is formed on the metal cover at the contact surface between the metal layer 7, and set the flux layer 11 in contact with the metal layer 7, to temporarily attach the metal lid 5 to the metal layer 7. Then, the metal lid 5 is sealed to the ceramic substrate 1 by the metal layer 7. Therefore, when sealing the ceramic substrate 1 and the metal lid 5 with a metal material, this method provides effects capable of temporarily fixing the metal lid 5 to the ceramic substrate 1 with the flux layer 11, and further releasing the outgas generated by the sealing process effectively and completely. Accordingly, the crystal unit of the second application, is capable of using metal sealant while achieving airtightness to provide a high quality crystal unit.

[Third Application: FIG. 16]

Next, a description will be given of the surface mounting quartz crystal unit of a third application according to the embodiment of this disclosure with reference to FIG. 16. FIG. 16 is an explanatory cross-sectional view of a unit of a third application. The crystal unit of the third application, as illustrated in FIG. 16, is configured to apply a heat-resistant resin to the entire front surface to form a heat-resistant resin layer 12 after sealing the metal of the crystal unit.

As the heat-resistant resin layer 12, a polyimide having heat resistance up to about 350° C. and the like are used, coated by spraying. If the spray coating is performed, a resin film of a heat resistant resin (the heat-resistant resin layer 12) can be conformally (shape-applicably) formed on the entire front surface of the ceramic substrate 1. The heat-resistant resin layer 12 is finally formed after the metal pattern of the holding terminal 2 is formed on the ceramic sheet, the crystal unit element such as the crystal element 4 is formed to mount the metal lid 5, and the metal is sealed. After the heat-resistant resin layer 12 is formed, the ceramic sheet is divided by the break line, and the ceramic sheet is divided into separate crystal units.

In the crystal unit, a gold alloy is preferable as the sealing metal (sealing material) of the metal layer 7. However, in order to reduce costs, a material other than gold, such as silver-tin, may be used. In this case, since the melting point of the sealing metal other than gold becomes 300° C. or less, remelting of the sealing material is a concern during the reflow processing at customer sites. For example, a gold-tin does not melt at 300° C., but a solder and silver-tin melts at about 280° C. On the other hand, heat-resistant resin such as polyimide do not transition until 350° C. However, gas is generated, but the metal lid 5 is sealed to the ceramic substrate 1 by the metal, so the gas is prevented from entering the inside of the metal lid 5.

[Effect of Third Application]

According to the crystal unit of the third application, the metal lid 5 is sealed on the metal layer 7 by metal, the heat-resistant resin layer is applied to the entire front surface, and the heat-resistant resin layer 12 is formed. Therefore, there is an effect capable of preventing remelting of the sealing material during the reflow processing at customer sites.

[Fourth Application: FIG. 17]

Next, a description will be given of the surface mounting quartz crystal unit of a fourth application according to the embodiment of this disclosure with reference to FIG. 17. FIG. 17 is an explanatory cross-sectional view of a unit of a fourth application. The crystal unit of the fourth application, as illustrated in FIG. 17, is configured to form a plating layer 13 by plating the crystal unit so as to cover the metal lid 5 and the metal layers (metal bonding) 7 after sealing the metal of the crystal unit.

The plating layer 13 is formed of nickel, copper, and the like so as to cover the front surface and the side surface of the metal lid 5, and the side surface of the metal layer 7 with electrolytic plating, for example. When a material other than gold is used for sealing the metal, remelting of the sealing material is a concern during reflow processing at customer sites. On the other hand, when the plating layer 13 that covers the metal cover 5 and the metal layers 7 is formed, remelting of the sealing material is prevented.

The plating layer 13 is finally formed after the metal pattern of the holding terminal 2 is formed on the ceramic sheet, the crystal unit element such as the crystal element 4 is formed to mount the metal lid 5, and the metal is sealed. After the plating layer 13 is formed, the ceramic sheet is divided by the break line, and the ceramic sheet is divided into separate crystal units.

[Effect of the Fourth Application]

According to the crystal unit of the fourth application, the metal lid 5 is sealed on the metal layers 7 by metal, the plating layer 13 is formed so as to cover the front surface and the side surface of the metal lid 5, and the side surface of the metal layers 7. Therefore, there is an effect capable of preventing remelting of the sealing material during the reflow processing at customer sites.

[Combinations]

The crystal unit and first to the fourth applications are described above; however, the surface mounting quartz crystal unit can be arranged by arbitrarily combining these embodiments as much as possible.

[Effect of the Embodiments]

According to the surface mounting quartz crystal unit and the tuning-fork quartz crystal unit that are described above, when a configuration where the ceramic sheet and the metal lid 5, 5′ are sealed with the metal layer 7 is adopted, this has effects capable of blocking noises from outside the metal lid 5, 5′ to the crystal element 4 inside the metal lid 5, 5′, and improving the airtightness and the electrical characteristics.

### INDUSTRIAL APPLICABILITY

This disclosure preferably applies to a surface mounting quartz crystal unit and the method of fabricating the same such that noises from outside the metal lid to the crystal resonator inside the metal lid can be blocked, and the airtightness and the electrical characteristics can be improved when a configuration where the ceramic sheet and the metal lid are sealed with a metal layers is adopted.

In the surface mounting quartz crystal unit, the second through via may have a connection portion on the front surface of the substrate, the connection portion being formed under the metal layer at a corner or a vicinity of the corner of the metal layer.

A surface mounting quartz crystal unit may include a ceramic substrate, a holding terminal, a metal cover, a signal line terminal and a ground terminal, and a metal layer. The holding terminal holds a crystal resonator on the substrate. The metal cover is arranged to cover the crystal resonator. The signal line terminal and a ground terminal are formed on a rear surface of the substrate. The metal layer bonds the substrate to the metal cover at a part on a front surface of the substrate, the part being in contact with the metal cover. The substrate has a first through via inside the substrate. The first through via connects the holding terminal to the signal line terminal. The substrate has a through terminal on a side surface at a corner portion of the substrate. The through terminal connects the metal layer to the ground terminal.

In the surface mounting quartz crystal unit, the through terminal may have a connection portion on the front surface of the substrate, the connection portion connecting to the metal layer at a corner or a vicinity of the corner of the metal layer.

In the surface mounting quartz crystal unit, the holding terminal may be a double-sided unit that holds two opposite sides of the crystal resonator.

In the surface mounting quartz crystal unit, the holding terminal may be a cantilevered unit that holds the two points of the one side of the crystal resonator.

In the surface mounting quartz crystal unit, the crystal resonator may have a rectangle shape.

In the surface mounting quartz crystal unit, the crystal resonator may have a shape of a tuning-fork.

A surface mounting quartz crystal unit may include a ceramic substrate, a holding terminal, a metal cover, a signal line terminal and a ground terminal, and a metal layer. The holding terminal holds a crystal resonator on the substrate. The metal cover is arranged to cover the crystal resonator. The signal line terminal and the ground terminal formed on a rear surface of the substrate. The metal layer bonds the substrate to the metal cover at a part on a front surface of the substrate. The part is in contact with the metal cover. The substrate has a first through via inside the substrate. The first through via connects the holding terminal to the signal line terminal. The substrate has a second through via inside the substrate. The second through via connects the metal layer to the ground terminal. The metal cover has a flux layer for temporary attaching between the metal cover and the metal layer.

In the surface mounting quartz crystal unit, the flux layer may be partially formed on a contact surface between the metal cover and the metal layer.

In the surface mounting quartz crystal unit, the metal cover may be mounted on the ceramic substrate, and a heat-resistant resin layer is formed so as to cover an entire front surface such that the metal cover is bonded with the substrate by the metal layer.

In the surface mounting quartz crystal unit, the metal cover is mounted on the ceramic substrate, and a plating layer is formed so as to cover a front surface and a side surface of the metal cover, and a side surface of the metal layer in a state where the metal cover is bonded with the substrate by the metal layer.

In the surface mounting quartz crystal unit, the metal cover may include a flange.

In the surface mounting quartz crystal unit, the metal cover may have a U-shaped structure without a flange.

A method of fabricating a surface mounting quartz crystal unit includes: forming a first through via and a second through via that penetrate through a front surface and a rear surface of a ceramic substrate so as to electrically connect the front surface to the rear surface of the substrate; forming, on the rear surface of the substrate, a signal line terminal that connects to the first through via and a ground terminal that connects to the second through via; forming a holding terminal that connects to the first through via on the front surface of the substrate; and forming a metal layer that bonds the substrate to the metal cover at a part that connects to the second through via on the front surface of the substrate, the part being in contact with the metal cover.

In the method of fabricating the surface mounting quartz crystal unit, the second through via may have a connection portion on the front surface of the substrate, the connection portion being formed under the metal layer at a corner or a vicinity of the corner of the metal layer.

A method of fabricating the surface mounting quartz crystal unit includes: forming a first through via and a second through via that penetrate through a front surface and a rear surface of a ceramic substrate so as to electrically connect the front surface to the rear surface of the substrate; forming, on the rear surface of the substrate, a signal line terminal that connects to the first through via and a ground terminal that connects to the second through via; forming a holding terminal that connects to the first through via on the front surface of the substrate; forming a metal layer that bonds the substrate to the metal cover at a part that connects to the second through via on the front surface of the substrate, the part being in contact with the metal cover; mounting a crystal resonator on the holding terminal; installing the metal cover having a contact surface with a flux layer to cover the crystal resonator such that the flux layer contact with the metal layer, so as to temporary attach the metal cover to the metal layer; and sealing the metal cover on the substrate.

In the method of fabricating the quartz crystal unit, the flux layer may be partially formed on a contact surface between the metal cover and the metal layer.

With this disclosure, a surface mounting quartz crystal unit is configured to form a signal line terminal and a ground terminal on the rear surface of the substrate, to form a metal layer that bonds the substrate to the metal cover at the part that is in contact with the metal cover on the front surface of the substrate, to connect a holding terminal and the signal line terminal though a first through via that is formed in the substrate, and to connect the metal layer and the ground terminal though a second through via that is formed in the substrate. Therefore, when a configuration that the ceramic sheet and the metal cover are sealed with the metal layer is adopted, this has effects capable of blocking noises from outside the metal cover to the crystal resonator inside the metal cover, and improving the airtightness and the electrical characteristics.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A surface mounting quartz crystal unit, comprising:
a ceramic substrate;
a holding terminal that holds a crystal resonator on the ceramic substrate;
a metal cover arranged to cover the crystal resonator;
a signal line terminal and a ground terminal formed on a rear surface of the ceramic substrate; and
a metal layer that bonds the ceramic substrate to the metal cover at a part on a front surface of the ceramic substrate, the part being in contact with the metal cover, wherein
the ceramic substrate has a first through via inside the ceramic substrate, the first through via connecting the holding terminal to the signal line terminal; and
the ceramic substrate has a through conductor at the ceramic substrate, the through conductor connecting the metal layer to the ground terminal.

2. The surface mounting quartz crystal unit according to claim 1, wherein
the through conductor is a second through via inside the ceramic substrate.

3. The surface mounting quartz crystal unit according to claim 2, wherein
the second through via has a connection portion on the front surface of the ceramic substrate, the connection portion being formed under the metal layer at a corner or a vicinity of the corner of the metal layer.

4. The surface mounting quartz crystal unit according to claim 1, wherein
the through conductor is a through terminal on a side surface at a corner portion of the ceramic substrate.

5. The surface mounting quartz crystal unit according to claim 4, wherein
the through terminal has a connection portion on the front surface of the ceramic substrate, the connection portion connecting to the metal layer at a corner or a vicinity of the corner of the metal layer.

6. The surface mounting quartz crystal unit according to claim 1, wherein
the holding terminal is a double-sided unit that holds two opposite sides of the crystal resonator.

7. The surface mounting quartz crystal unit according to claim 1, wherein
the holding terminal is a cantilevered unit that holds two points of one side of the crystal resonator.

8. The surface mounting quartz crystal unit according to claim 6, wherein
the crystal resonator has a rectangle shape.

9. The surface mounting quartz crystal unit according to claim 7, wherein
the crystal resonator has a shape of a tuning-fork.

10. The surface mounting quartz crystal unit according to claim 1, wherein
the metal cover has a flux layer for temporary attaching between the metal cover and the metal layer.

11. The surface mounting quartz crystal unit according to claim 10, wherein
the flux layer is partially formed on a contact surface between the metal cover and the metal layer.

12. The surface mounting quartz crystal unit according to claim 1, wherein
the metal cover is mounted on the ceramic substrate, and a heat-resistant resin layer is formed so as to cover an entire front surface in a state where the metal cover is bonded with the substrate by the metal layer.

13. The surface mounting quartz crystal unit according to claim 1, wherein
the metal cover is mounted on the ceramic substrate, and
a plating layer is formed so as to cover a front surface and a side surface of the metal cover, and a side surface of the metal layer in a state where the metal cover is bonded with the ceramic substrate by the metal layer.

14. The surface mounting quartz crystal unit according to claim 1, wherein
the metal cover includes a flange.

15. The surface mounting quartz crystal unit according to claim 1, wherein
the metal cover has a U-shaped structure without a flange.

16. A method of fabricating a surface mounting quartz crystal unit of claim 1, comprising:
forming a first through via and a through conductor that penetrate through a front surface and a rear surface of a ceramic substrate so as to electrically connect the front surface to the rear surface of the ceramic substrate;
forming, on the rear surface of the ceramic substrate, a signal line terminal that connects to the first through via and a ground terminal that connects to the through conductor;
forming a holding terminal that connects to the first through via on the front surface of the ceramic substrate; and
forming a metal layer connecting to the through conductor, that bonds the ceramic substrate to the metal cover at a part on the front surface of the ceramic substrate, being in contact with the metal cover.

17. The method of fabricating the surface mounting quartz crystal unit according to claim 16, wherein
the through conductor is a second through via inside the ceramic substrate,
the second through via has a connection portion on the front surface of the ceramic substrate, the connection portion being formed under the metal layer at a corner or a vicinity of the corner of the metal layer.

18. The method of fabricating the surface mounting quartz crystal unit according to claim 16, further comprising:
mounting a crystal resonator on the holding terminal;
installing the metal cover having a contact surface with a flux layer to cover the crystal resonator such that the flux layer contact with the metal layer, so as to temporary attach the metal cover to the metal layer; and
sealing the metal cover on the ceramic substrate.

19. The method of fabricating the quartz crystal unit according to claim 18, wherein
the flux layer is partially formed on a contact surface between the metal cover and the metal layer.
